(19) United States
(12) Patent Application Publication
(10) Pub. No.: US 2016/0050772 A1
(43) Pub. Date: Feb. 18, 2016

(54) DISPLAY DEVICE

(71) Applicant: SAMSUNG ELECTRONICS CO., LTD., Suwon-si (KR)

(72) Inventors: Jae Hoo PARK, Suwon-si (KR); Jun Pil OH, Suwon-si (KR); Jun Ki NOH, Uiwang-si (KR); Gyu Sung DO, Seoul (KR); Woo Sung IN, Hwaseong-si (KR)

(73) Assignee: SAMSUNG ELECTRONICS CO., LTD., Suwon-si (KR)

(21) Appl. No.: 14/744,331

(22) Filed: Jun. 19, 2015

(30) Foreign Application Priority Data
Aug. 12, 2014 (KR) 10-2014-0104491

(51) Int. Cl. H05K 5/00; H05K 5/02

(52) U.S. Cl. CPC H05K 5/0021; H05K 5/0017; H05K 5/0004; H05K 5/0234

(57) ABSTRACT

A display device is provided. The display device includes a display module; and a transforming device configured to transform the display module between a flat state and a curved state. The transforming device includes a base panel provided behind the display module at a center portion of the display panel along a width direction of the display module, and a pair of rotating panels, each of the pair of rotating panels having a first end rotationally engaged with the base panel and a second end opposite to the first end attached to opposite ends of the display module along the width direction.

### CROSS-REFERENCE TO RELATED APPLICATION

This application claims priority from Korean Patent Application No. 10-2014-0104491, filed on Aug. 12, 2014 in the Korean Intellectual Property Office, the entire disclosure of which is incorporated herein by reference in its entirety.

### BACKGROUND

1. Technical Field

Apparatuses consistent with exemplary embodiments relate to a display device, and more particularly to a display device having a display module transformable into a flat or curved form and a driver for transforming the display module.

2. Description of the Related Art

Display devices, such as televisions or monitors, display received signals into images.

Recently, a display device having a curved display module with the left and right ends coming forward relative to a center portion of the display module has emerged where the display device gives an effect of making a two-dimensional (2D) image appear as three-dimensional (3D).

### SUMMARY

One or more exemplary embodiments provide a display device with a display module that may be passively transformed into a flat or curved form.

In accordance with an aspect of an exemplary embodiment, there is provided a display device including: a display module; and a transforming device configured to transform the display module between a flat state and a curved state, wherein the transforming device includes: a base panel provided behind the display module at a center portion of the display panel along a width direction of the display module, and a pair of rotating panels, each of the pair of rotating panels having a first end rotationally engaged with the base panel and a second end opposite to the first end attached to opposite ends of the display module along the width direction.

A center portion of the display module may be fixedly attached to the base panel.

Each of the second ends of the pair of rotating panels may be movably attached to a respective end portion of the display module along the width direction.

Each of the pair of rotating panels may include a guide hole which extends in the width direction, and the display module may include guide pins configured to penetrate through the guide hole, thereby fastening the each of the pair of rotating panels to the display module.

The base panel may include a first hinge provided at each end along the width direction, each of the pair of rotating panels rotatably engaged with a respective first hinge provided at each end along the width direction, where each of the pair of rotating panels may include a second hinge arranged at an inner end of each of the pair of rotating panels and rotatably attached to the respective first hinge, and where the transforming device may include a hinge pin penetrating through the first and the second hinges.

Each the pair of rotating panels may include a handle arranged on s rear face of each the pair of rotating panels.

The display device may further include: a case accommodating the display module and the transforming device, where the case includes a through hole to expose the handle.

The transforming device may be configured to transform the display module between the flat state and the curved state via external force manually applied from an exterior source outside of the display device.

In accordance with an aspect of another examplary embodiment, there is provided a display device including: a display module; and a transforming device configured to transform the display module from between a flat state and a curved state, wherein the transforming device includes: a base panel provided behind the display module at a center portion of the display panel along a width direction of the display module; and a pair of locking panels, each of the pair of locking panels engaged with a respective end of the display module along a width direction and curvedly extending forward of the base panel, and wherein the display device may further include a locking projection which protrudes from one of a front face of the base panel and a rear face of the pair of locking panels, and a locking groove arranged on the other of the front face of the base panel and the rear face of the pair of locking panels configured to engage with the locking projections.

The pair of locking panels may be made of elastically transformable material and includes an arc-shaped cross-section.

The locking projection may be provided on the base panel, and the locking groove may be provided on a front face of each of the pair of locking panels.

The locking projection may protrude forward from the front face of the base panel, and the locking groove may be provided at an inner end of the rear face of the locking panel along the width direction.

The locking groove may include a plurality of locking grooves provided in a row in the width direction of the display module.

The transforming device may be configured to transform the display module between the flat state and the curved state via external force manually applied from an exterior source outside of the display device.

In accordance with an aspect of another examplary embodiment, there is provided a display device including: a display unit configured to display a screen; and a stand configured to support the display unit, wherein the stand may include: a base provided on a plane, and a supporting member movably installed along a curved path on the base at a first end and coupled with the display unit at the second end opposite to the first end.

The base may include a driver configured to move the supporting member.

The base may include: a base housing accommodating the driver; and a base cover covering a top of the base housing, and the base cover includes a guide slot which extends in an arc for guiding movement of the supporting member.

The driver may include: a motor configured to generate power, and a rag body configured to move according to the power delivered from the motor through at least one gear, and the supporting member may be connected to the rag body at the first end and is configured to move with the rag body.

The rag body may extend in an arc.

The at least one may include: a worm installed on the motor, and a worm wheel interlocking with the worm and the rag body.

### BRIEF DESCRIPTION OF THE DRAWINGS

The above and/or other aspects will become more apparent by describing in detail exemplary embodiments with reference to the attached drawings in which:

FIG. 1 is a perspective view of a display device with a flat display module according to an exemplary embodiment;

FIG. 2 is a perspective view of a display device with a curved display module according to an exemplary embodiment;

FIG. 3 is an exploded view of a display device according to an exemplary embodiment;

FIG. 4 is a rear view of a transforming device of a display device with a flat display module according to an exemplary embodiment;

FIG. 5 is a rear view of a transforming device of a display device with a curved display module according to an exemplary embodiment;

FIG. 6 is an enlarged view of portion A of FIG. 4;

FIG. 7 is an enlarged view of portion B of FIG. 4;

FIG. 8 is a cross-sectional view of a display device with a flat display module, according to an exemplary embodiment;

FIG. 9 is a cross-sectional view of a display device with a curved display module, according to an exemplary embodiment;

FIG. 10 is an exploded view of a display device according to an exemplary embodiment;

FIG. 11 is a rear view of a transforming device of a display device with a curved display module according to an exemplary embodiment;

FIG. 12 is an enlarged view of portion C of FIG. 11;

FIG. 13 is a cross-sectional view of a display device with a flat display module according to an exemplary embodiment;

FIG. 14 is a cross-sectional view of a display device with a curved display module, according to an exemplary embodiment;

FIG. 15 is a perspective view of a display device with a display unit located in the center according to an exemplary embodiment;

FIG. 16 is an exploded view of a display device, according to an exemplary embodiment; and

FIG. 17 is a perspective view of a display device with a display unit moved and rotated to a side according to an exemplary embodiment.

### DETAILED DESCRIPTION

Exemplary embodiments of a display device in accordance with the present disclosure will now be described with reference to accompanying drawings. Throughout the drawings, like reference numerals will be understood to refer to like parts, components, and structures.

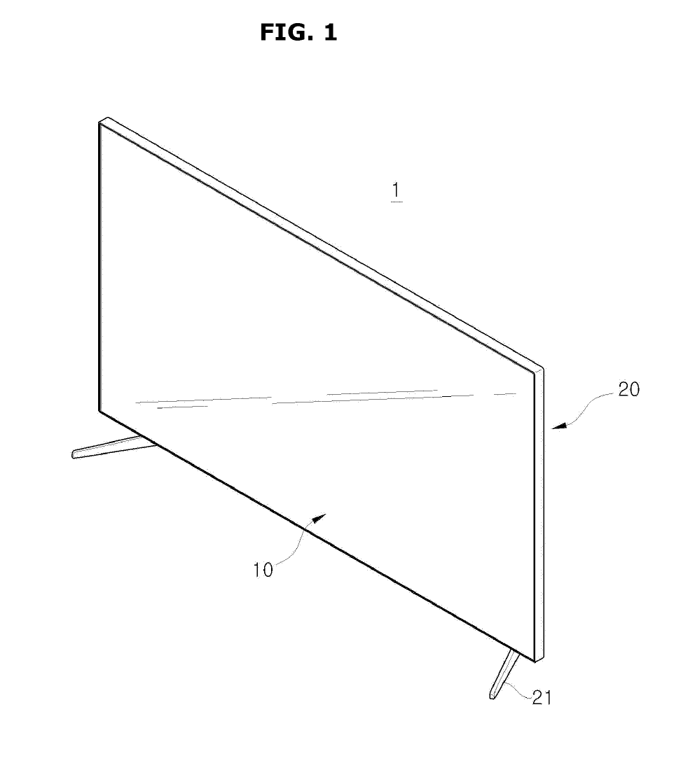

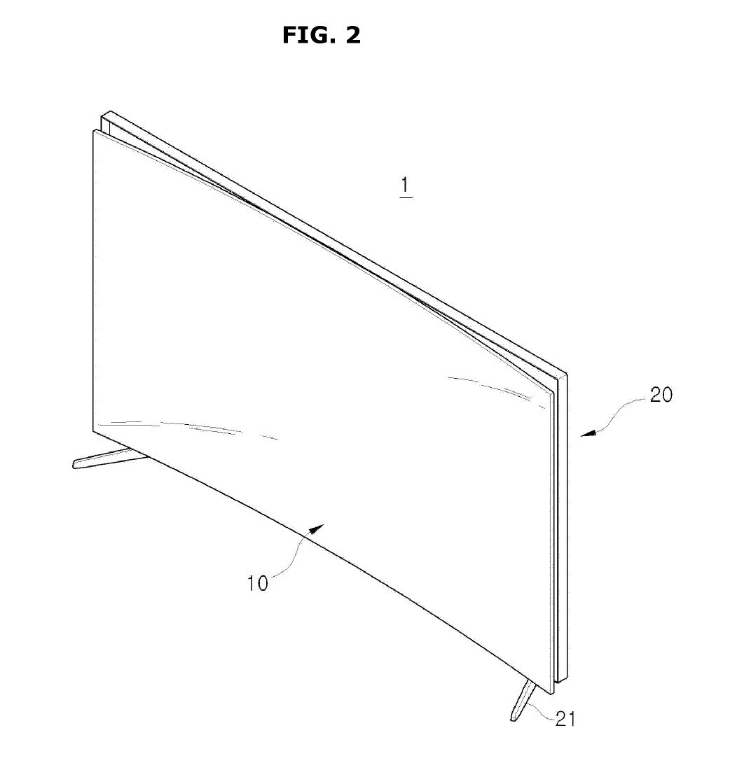

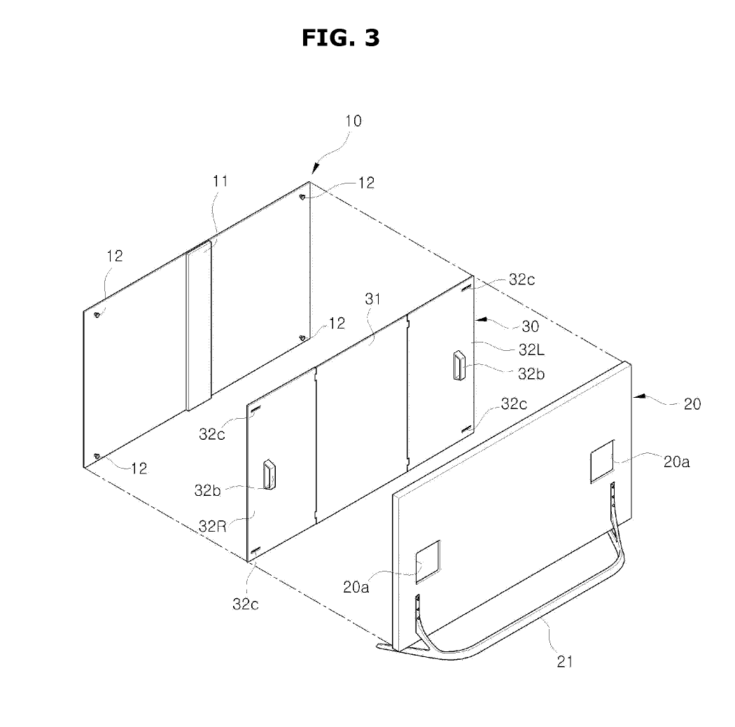

FIG. 1 is a perspective view of a display device 1 with a display module 10 in a flat state according to an exemplary embodiment and FIG. 2 is a perspective view of a display device 1 with a display module 10 in a curved state according to an exemplary embodiment. FIG. 3 is an exploded view of a display device 1 according to an exemplary embodiment. As shown in FIGS. 1 and 2, a display device 1 in accordance with the exemplary embodiment may include a display module 10 which may be transformed into a flat shape, or into a curved shape with both ends coming forward relative to a center portion of the display module 10, and a case 20 that contains the display module 10.

The display device 1 may also include a transforming device 30 as shown in FIG. 3, which is arranged behind the display module 10 to allow the user to transform the display module 10 between the flat state and the curved state.

Although not shown, the display module 10 may include a display panel made of a liquid crystal panel, a back light for supplying light to the display panel, or the like. Alternatively, the display panel may be an organic light emitting diode (OLED) panel.

The case 20 may enclose the display module 10 and the transforming device 30, and include a stand 21 supporting the display device 1 to be installed upright on a surface. While the stand 21 is installed on the case 20 in the exemplary embodiment, it is not limited thereto. For example, the stand 21 may be installed on a base panel 31 as described below.

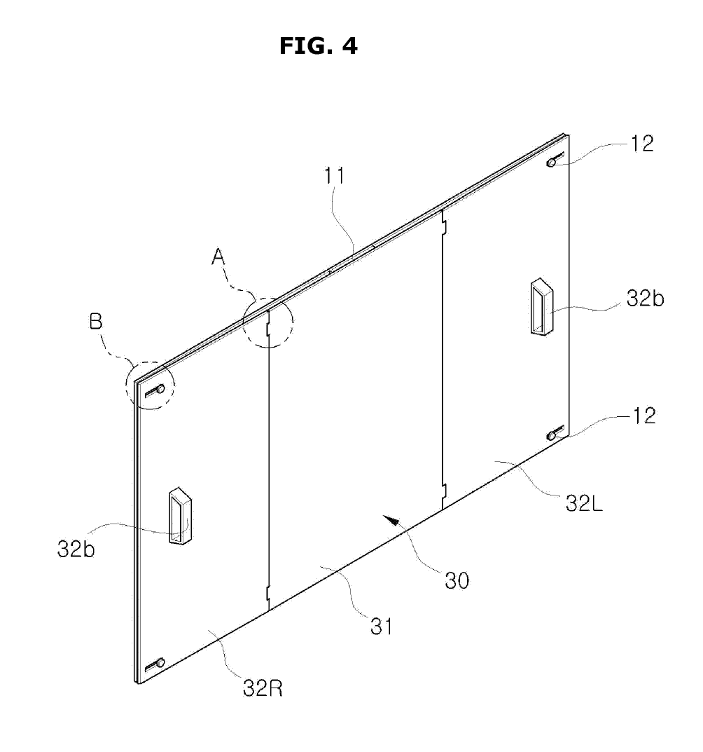

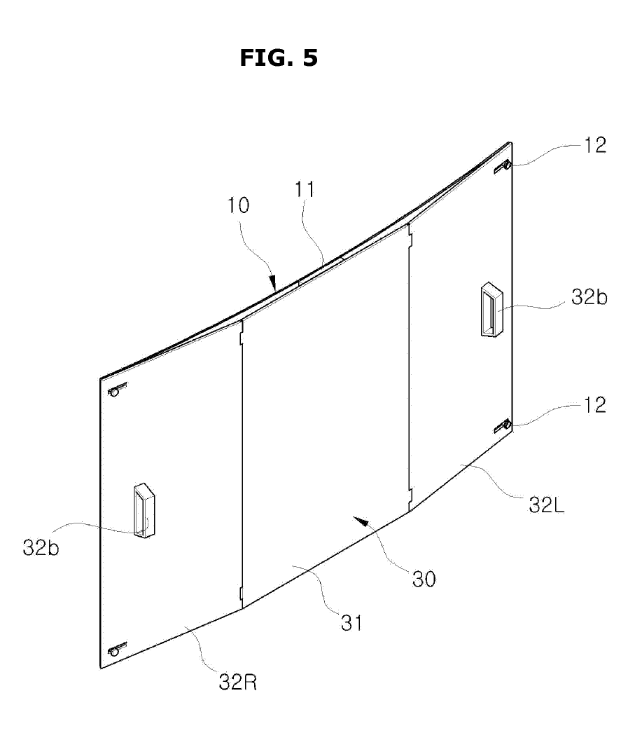

FIG. 4 is a rear view of a transforming device 30 of a display device 1 with a display module 10 in a flat state according to an exemplary embodiment. FIG. 5 is a rear view of a transforming device 30 of a display device 1 with a display module 10 in a curved state according to an exemplary embodiment. The transforming device 30 may include the base panel 31 which is rectangular shaped and arranged at a center portion of the rear of the display module 10, and rotating panels 32L and 32R rotationally installed/attached on either side of the base panel 31 at one end of each of the rotating panels 32L and 32R. The other end of each of the rotating panels 32L and 32R are installed/attached on the display module 10. As shown in FIGS. 4 and 5, rotating the rotating panels 32L and 32R with respect to the base panel 31 may enable the display module 10 to be transformed into a flat state or a curved state.

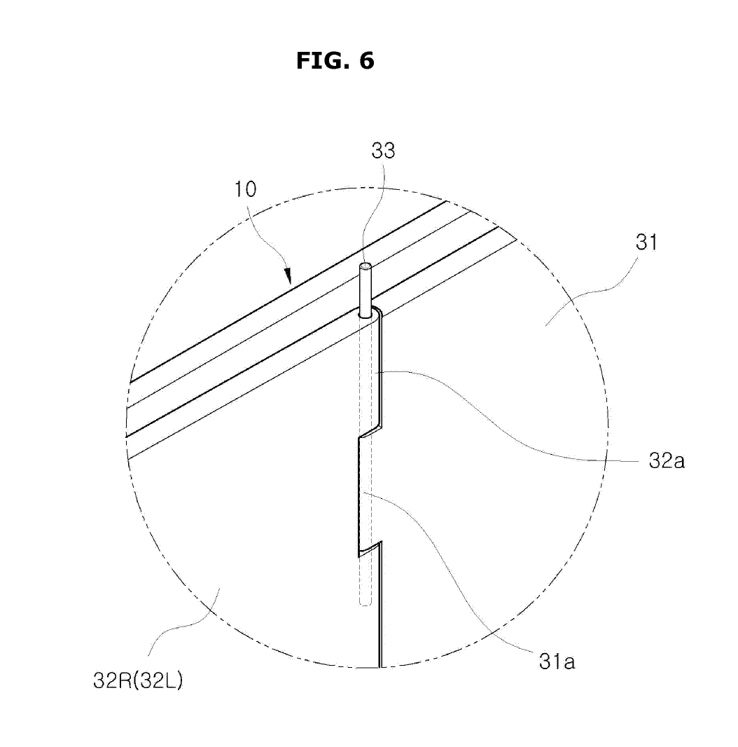

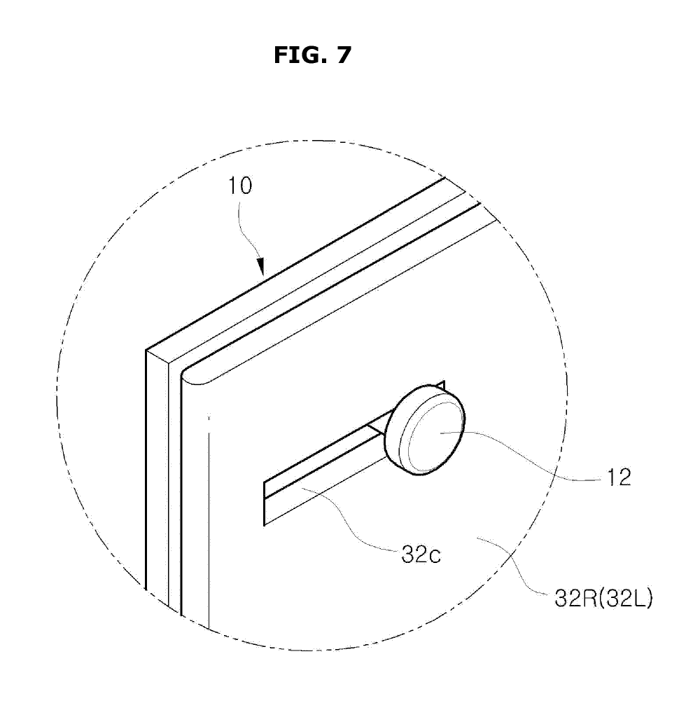

FIG. 6 is an enlarged view of portion A of FIG. 4 and FIG. 7 is an enlarged view of portion B of FIG. 4. Referring to FIG. 6, a first hinge 31a is formed at both ends of the base panel 31 for the rotating panels 32L and 32R to be rotationally installed on the base panel 31, and a second hinge 32a is formed at a corresponding end of each of the two rotating panels 32L and 32R to be rotationally installed on the first hinges 31a on the base panel 31. In the exemplary embodiment, the first and the second hinges 31a and 32a are attached to each other by penetrating a hinge pin 33 to penetrate the first and the second hinges 31a and 32, such that the rotating panels 32L and 32R are rotatably installed on the base panel 31 to be rotatable with respect to the hinge pin 33.

Referring back to FIG. 3, a center portion of the display module 10 may be fixed to a corresponding center portion of the base panel 31 via a fastening member 11 provided on the rear of the display module 10 at the center portion.

The two rotating panels 32L and 32R may include respective handles 32b for the user to apply forces on the rotating panels 32L and 32R. The handles 32b may be installed on the rear face of the two rotating panels 32L and 32R, and through holes 20a may be provided on the case 20 for the user to hold the handles 32b from outside of the case 20.

As described above, each of the rotating panels 32L and 32R may have one end rotationally installed on opposite sides of the base panel 31 and the other end (i.e., the outer ends) of each of the rotating panels 32L and 32R may be movably mounted on the rear face of the display module 10. With the above-described arrangement, the display module 10 may be transformed between the flat state and the curved state in response to the rotating panels 32L and 32R rotating with respect to the base panel 31.

Referring now to FIG. 7, in order to movably install the other ends (i.e., the outer ends) of the rotating panels 32L and 32R on the rear face of the display module 10, respective guide holes 32c are formed on the rotating panels 32L and 32R to extend in the width direction of the display device 1, and respective guide pins 12 are provided on the rear face of the display module 10 to pass through the guide holes 32c and be movable within the guide holes 32c. In the exemplary embodiment, the guide holes 32c are formed on upper and lower parts of the other ends (i.e., the outer ends) of the two rotating panels 32L and 32R, and a total of four (4) guide pins 12 may be formed on upper and lower parts of both sides of the rear face of the display module 10.

In the following description, a transformation process of the display module 10 of the display device 1 will be described in more detail with reference to accompanying drawings.

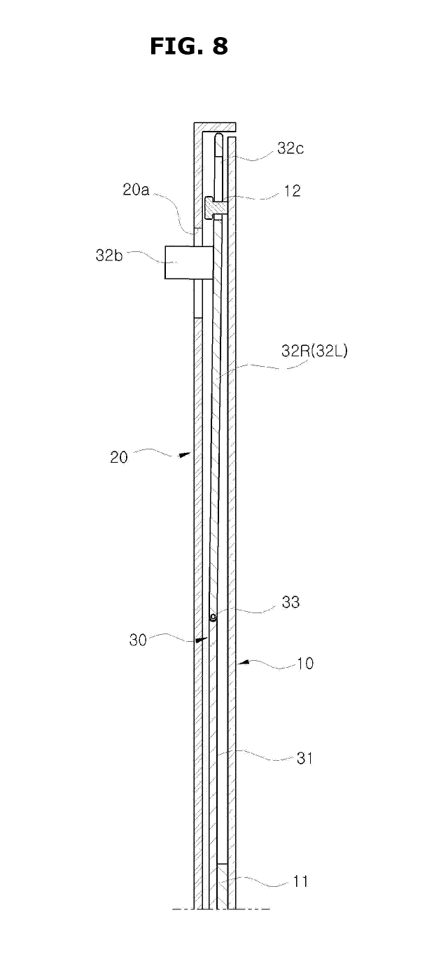

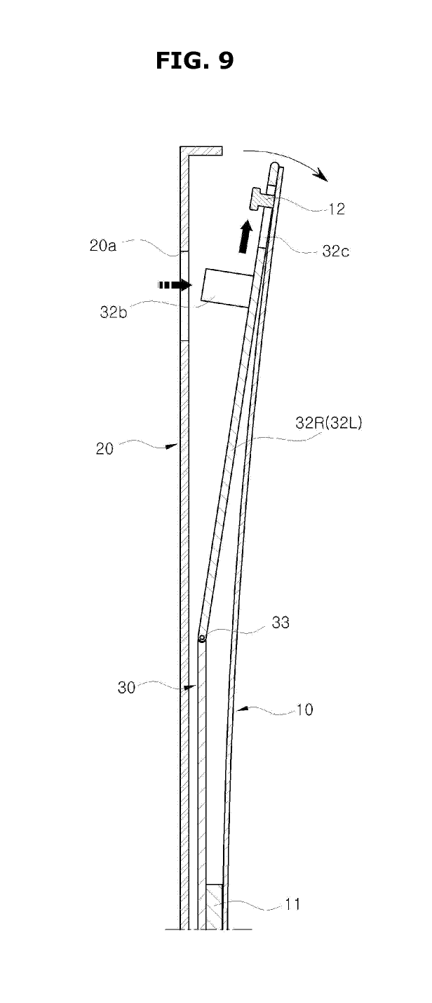

FIG. 8 is a cross-sectional view of a display device 1 with a display module 10 in a flat state according to an exemplary embodiment. FIG. 9 is a cross-sectional view of a display device 1 with a display module 10 in a curved state according to an exemplary embodiment.

First, referring to FIG. 8, while the display module 10 is in the flat state, the rotating panels 32l and 32R remain in the same plane as the base panel 31.

When the display module 10 is to be transformed into a curved state as shown in FIG. 9, the user may apply force on the two rotating panels 32L and 32R via the respective handles 32b such that the rotating panels 32L and 32R are each rotated around respective ends of the base panel 31 until the other end (i.e., the outer ends) of the rotating panel 32L or 32R rotates forward.

As the other ends (i.e., the outer ends) of the rotating panels 32L and 32R rotates forward, opposite ends of the display module 10 in the width direction on which the other ends of the rotating panels 32L and 32R are installed move forward. At this time, because the center portion of the display module 10 is fixed onto the fastening member 11 of the base panel 31, the center portion of the display module 10 does not move while the opposite ends of the display module 10 rotate forward. Accordingly, the display module 10 is transformed into a curved state with opposite ends coming forward. Furthermore, as described above, as the guide pins 12 slide along the guide holes 32c, opposite ends of the display module 10 are moved a predetermined distance apart from the outer ends of the rotating panels 32L and 32R in the transformation process of the display module 10, which makes the transformation of the display module 10 more smoothly.

Another exemplary embodiment of a display device 1 in accordance with the present disclosure will now be described with reference to accompanying drawings.

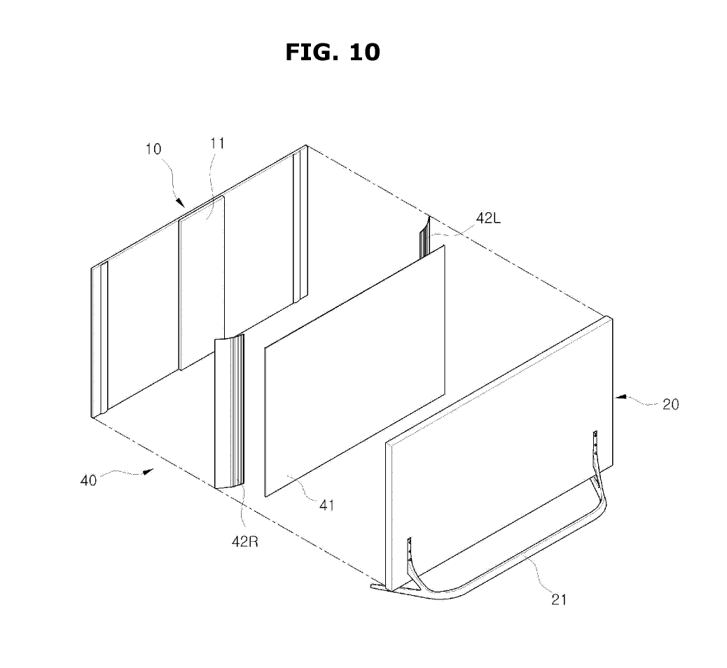

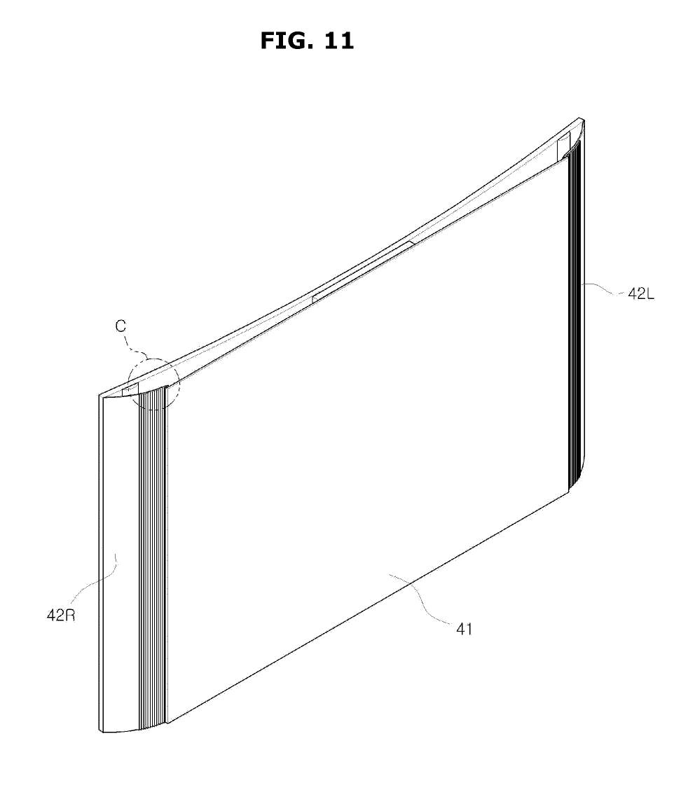

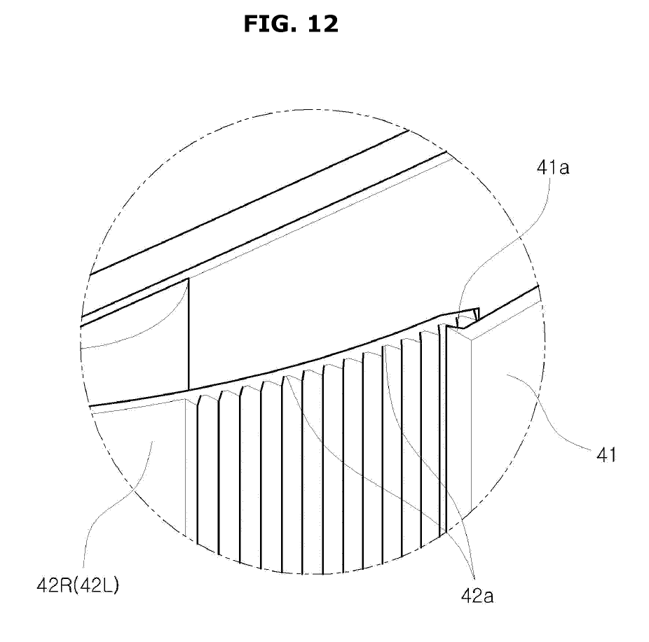

FIG. 10 is an exploded view of a display device 1 with a transforming device 40 according to an exemplary embodiment. FIG. 11 is a rear view of a transforming device 40 of a display device 1 with a display module 10 in a curved state according to an exemplary embodiment and FIG. 12 is an enlarged view of portion C of FIG. 11.

Referring to FIGS. 10 and 11, a transforming device 40 for transforming the display module 10 between a flat state and a curved state may include a base panel 41 arranged behind the display module 10, and a pair of locking panels 42L and 42R having a curvature to extending forward from the base panel 41 to be installed on opposite sides of the display module 10.

The base panel 41 may be formed as substantially a rectangular plate with a narrower width compared to the display module 10, and the center part of the display module 10 may be fixedly attached to the center part of the base panel 41 via the fastening member 11 of the display module 10 fixed on the rear center of the display module 10. The base panel 41 may include a pair of locking projections 41a that protrude forward from both front ends to be caught by the locking panels 42L and 42R, as shown in FIG. 12. The locking projections 41a may be formed to have a triangular shaped cross-section protruding toward the display module 10 and may extend in the vertical direction.

As shown in FIG. 10, the locking panels 42L and 42R may be formed with an elastically transformable material. Each of the locking panels 42L and 42R may have one end (i.e., an outer end) installed on each of opposite sides of the display module 10 and the other end (i.e., an inner end) that extends backward while sloping inward and is engaged with the locking projections 41a of the base panel 41. Each of the two locking panels 42L and 42R may extend in an arc form with the rear face corresponding to the front face of the base panel 41 at each of the opposite sides of the base panel 41.

Each of the locking panels 42L and 42R may include locking grooves 42a formed on the rear face to be engaged with the locking projections 41a of the base panel 41 as shown in FIG. 12. The locking grooves 42a may be formed to have a corresponding triangular cross-section to be engaged with the locking projections 41a and may extend long in the vertical direction. In the exemplary embodiment, a plurality of locking grooves 42a may be formed in a row along the width direction of the display module 10, enabling the locking projection 41a to be fixedly attached to one of the plurality of locking grooves 42a, and thus adjusting the curvature of the display module 10 within a certain range.

Although the locking projections 41a are formed on the base panel 41 and the locking grooves 42a are formed on the locking panels 42L and 42R in the exemplary embodiment, the exemplary embodiments are not limited thereto. For example, it is possible for the locking grooves 42a to be formed on the base panel 41 and for the locking projections 41a to be formed on the locking panels 42L and 42R.

Furthermore, while there are a plurality of locking grooves 42a in the exemplary embodiment, the exemplary embodiments are not limited thereto and only a single locking groove may be formed in a position that corresponds to a curved state of the display module 10.

In the following description, a transformation process of the display module 10 of the display device 1 will be described in more detail with reference to accompanying drawings.

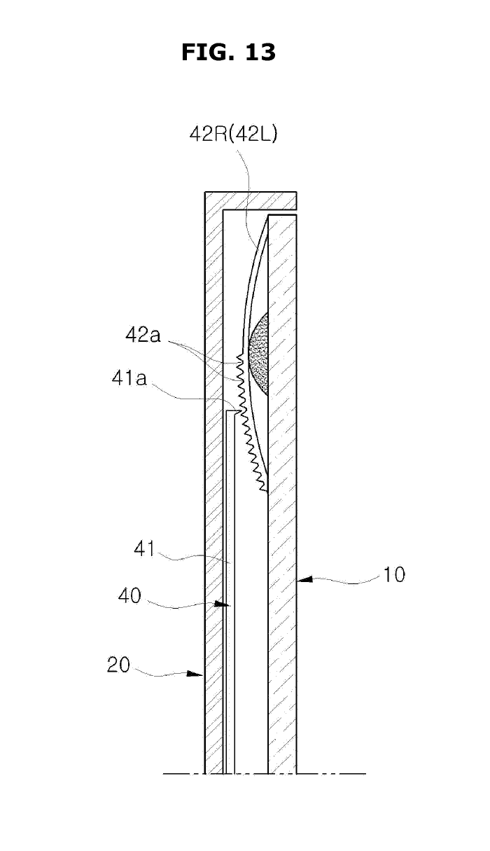

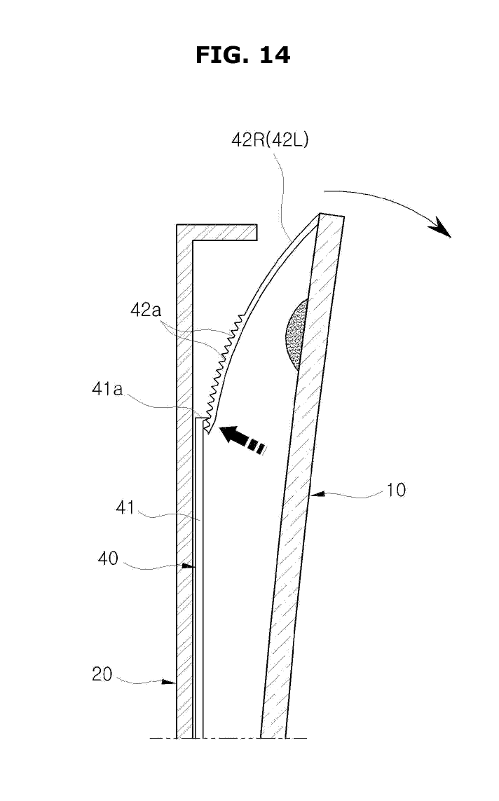

FIG. 13 is a cross-sectional view of a display device 1 with a display module 10 in a flat state according to an exemplary embodiment. FIG. 14 is a cross-sectional view of a display device 1 with a display module 10 in a curved state according to an exemplary embodiment.

First, referring to FIG. 13, while the display module 10 is in a flat state, the locking projection 41a remains fixedly engaged with a locking groove 42a among the plurality of locking grooves 41a, which is located at a position corresponding to an end of the locking panel 42L or 42R.

In this state, if the user applies force on opposite sides of the display module 10 to make the display module 10 to be transformed to have opposite ends of the display module move forward relative to the center part, the locking panels 42L and 42R may be temporarily transformed elastically due to the force applied to the display module 10. The transformation of the locking panels 42L and 42R may make the locking projections 41a disengage from the current locking grooves 42a and then engage with another locking groove of the plurality of locking grooves 42a provided at the outer ends of the locking panels 42L and 42R as shown in FIG. 14.

After the locking projections 41a are fixedly engaged with the another locking groove of the plurality of locking grooves 42a, even if the force applied to the display module 10 are released, the locking projections 41a are fixedly engaged with the another locking groove of the plurality of locking grooves 42a, thereby maintaining the display module 10 in a curved state with a certain curvature.

Yet another embodiment of a display device 1 in accordance with the present disclosure will now be described with reference to accompanying drawings.

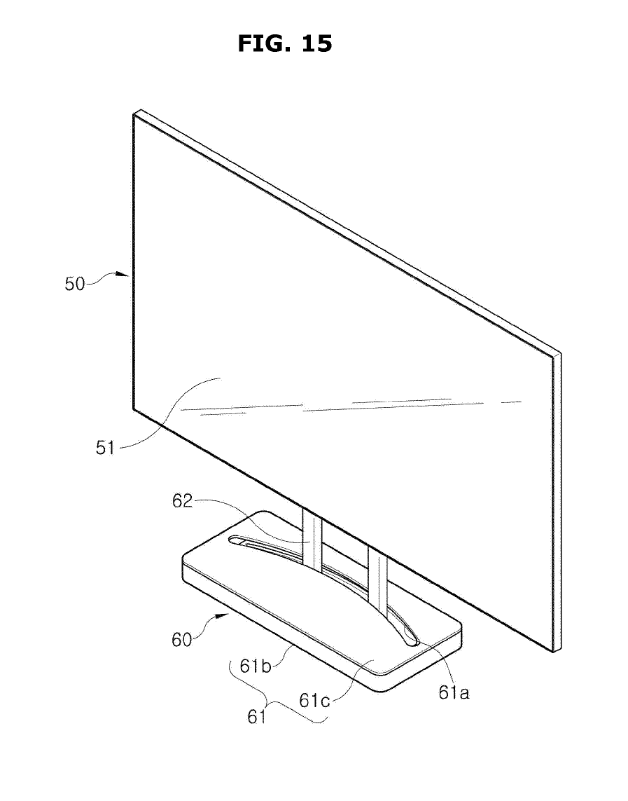

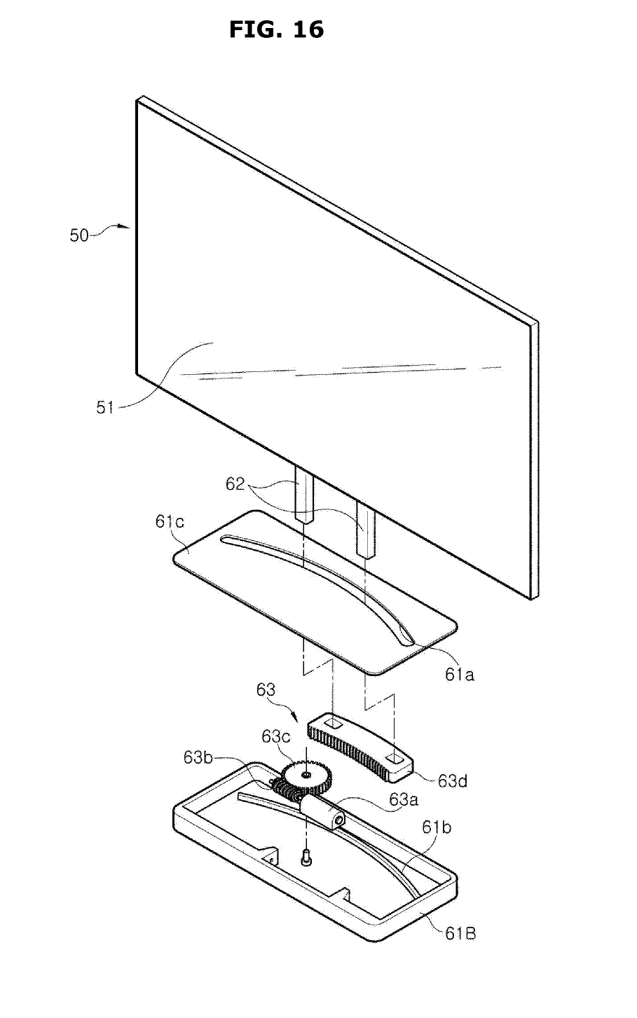

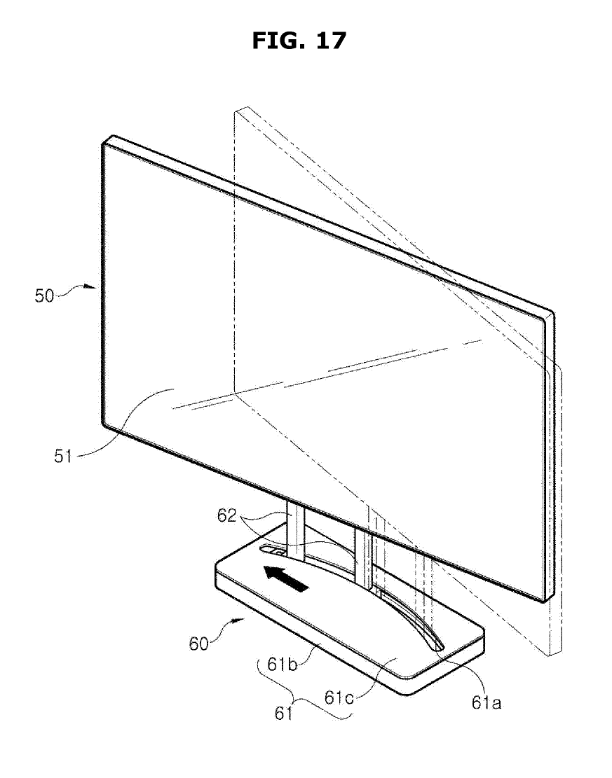

FIG. 15 is a perspective view of a display device 1 with a display unit 50 located in the center with respect to a stand 60 according to an exemplary embodiment. FIG. 16 is an exploded view of a display device 1 with a display unit 50 according to an exemplary embodiment. FIG. 17 is a perspective view of a display device 1 with a display unit 50 moved and rotated to a side with respect to a stand 60 according to an exemplary embodiment.

A display device may include a display unit 50 that has a display module 51 on which a screen is displayed, and a stand 60 that enables the display unit 50 to be installed upright on the horizontal plane. The stand 60 may include a base 61 supported by the horizontal plane, and a pair of supporting members 62 coupled with the base 61 on at one end and coupled with the display unit 50 on the other end.

The pair of supporting members 62 may be installed on the base 61 to be movable along a curved path, and the base 61 may include a driver 63 for moving the supporting members 62.

The base 61 may include a base housing 61B with an open top for containing the driver 63, and a base cover 61C for covering the open top of the base housing 61B. In the base cover 61C, a guide slot 61a is formed to extend in an arc form for guiding the supporting members 62 coupled with the display unit 50 along the curved arc form. On the bottom of the base housing 61B, a guide rib 61b may be formed to protrude upward and extend to in the width direction of the display unit 50 along a corresponding arc form for guiding the movement of a rag body 63d as described below.

The driver 63 may include a motor 63a for generating power, and the rag body 63d that moves by the power delivered from the motor 63a through gears 63b and 63c. In the exemplary embodiment, the rag body 63d may be formed to extend to the width direction in an arc form. The gears 63b and 63c may include a worm gear 63b installed on the axis of the motor 63a, and a worm wheel 63c interlocked with the worm gear 63b and rag body 63d.

Accordingly, when power is generated by the motor 63a, the rag body 63d may move in one direction in the width direction by the power delivered through the gears 63b and 63c. At this time, because the rag body 63d is guided by the arc-shaped guide rib 61b, and the supporting members 62 are guided by the arc-shaped guide slot 61a, the supporting members 62 and the display unit 50 coupled with the top of the supporting members 62 may be moved along the curved path. Accordingly, the display unit 50 may be moved and rotated as shown in FIG. 17.

Although the display device equipped with a flat-shaped display module 51 is taken as an example in the exemplary embodiment, the display device is not limited thereto, and the stand 60 may be applied as it is for a display device having a curved display module with both ends coming forward as discussed above, or a display device with a display module transformable into a flat or curved form.

According to the exemplary embodiments of the present disclosure, the user may transform a display module into a flat state or a curved state by rotating the display module or a rotating panel in person.

While exemplary embodiments have been particularly shown and described above, it would be appreciated by those skilled in the art that various modifications can be made without departing the scope of the inventive concept defined by the following claims.

What is claimed is:

1. A display device comprising:
a display module; and
a transforming device configured to transform the display module between a flat state and a curved state, the transforming device comprising:
a base panel provided behind the display module at a center portion of the display module along a width direction of the display module, and
a pair of rotating panels, each of the pair of rotating panels having a first end rotationally engaged with the base panel and a second end opposite to the first end attached to opposite ends of the display module along the width direction.

2. The display device of claim 1, wherein the center portion of the display module is fixedly attached to the base panel.

3. The display device of claim 1, wherein each of the second ends of the pair of rotating panels is movably attached to a respective end portion of the display module along the width direction.

4. The display device of claim 3, wherein each of the pair of rotating panels comprises a guide hole which extends in the width direction, and
wherein the display module comprises guide pins configured to penetrate through the guide hole, thereby fastening the each of the pair of rotating panels to the display module.

5. The display device of claim 1, wherein the base panel comprises a first hinge provided at each end along the width direction, each of the pair of rotating panels rotatably engaged with a respective first hinge provided at each end along the width direction,
wherein each of the pair of rotating panels comprises a second hinge arranged at an inner end of each of the pair of rotating panels and rotatably attached to the respective first hinge, and
wherein the transforming device comprises a hinge pin penetrating through the first and the second hinges.

6. The display device of claim 1, wherein each the pair of rotating panels comprises a handle arranged on s rear face of each the pair of rotating panels.

7. The display device of claim 6, further comprising: a case accommodating the display module and the transforming device,
wherein the case comprises a through hole to expose the handle.

8. The display device of claim 1, wherein the transforming device is configured to transform the display module between the flat state and the curved state via external force manually applied from an exterior source outside of the display device.

9. A display device comprising:
a display module; and
a transforming device configured to transform the display module from between a flat state and a curved state, the transforming device comprising:
a base panel provided behind the display module at a center portion of the display panel along a width direction of the display module; and
a pair of locking panels, each of the pair of locking panels engaged with a respective end of the display module along a width direction and curvedly extending forward of the base panel,
wherein the display device further comprises a locking projection which protrudes from one of a front face of the base panel and a rear face of the pair of locking panels, and a locking groove arranged on the other of the front face of the base panel and the rear face of the pair of locking panels configured to engage with the locking projections.

10. The display device of claim 9, wherein the pair of locking panels are made of elastically transformable material and comprises an arc-shaped cross-section.

11. The display device of claim 9, wherein the locking projection is provided on the base panel, and
wherein the locking groove is provided on a front face of each of the pair of locking panels.

12. The display device of claim 11, wherein the locking projection protrudes forward from the front face of the base panel, and
wherein the locking groove is provided at an inner end of the rear face of the locking panel along the width direction.

13. The display device of claim 12, wherein the locking groove comprises a plurality of locking grooves provided in a row in the width direction of the display module.

14. The display device of claim 9, wherein the transforming device is configured to transform the display module between the flat state and the curved state via external force manually applied from an exterior source outside of the display device.

15. A display device comprising:
a display unit configured to display a screen; and
a stand configured to support the display unit, the stand comprising:
a base provided on a plane, and
a supporting member movably installed along a curved path on the base at a first end and coupled with the display unit at the second end opposite to the first end.

16. The display device of claim 15, wherein the base comprises a driver configured to move the supporting member.

17. The display device of claim 16, wherein the base comprises:
a base housing accommodating the driver; and
a base cover covering a top of the base housing, and
wherein the base cover comprises a guide slot which extends in an arc for guiding movement of the supporting member.

18. The display device of claim 16, wherein the driver comprises:
a motor configured to generate power, and
a rag body configured to move according to the power delivered from the motor through at least one gear, and
wherein the supporting member is connected to the rag body at the first end and is configured to move with the rag body.

19. The display device of claim 18, wherein the rag body extends in an arc.

20. The display device of claim 18, wherein the at least one gear comprises:
a worm installed on the motor, and
a worm wheel interlocking with the worm and the rag body.
